(19) United States
(12) Patent Application Publication
(10) Pub. No.: US 2026/0208616 A1
(43) Pub. Date: Jul. 23, 2026

(54) METHOD FOR REMOTELY PERFORMING SELF-FAULT DIAGNOSIS IN ELECTRIC VEHICLE CHARGING SYSTEM AND APPARATUS SUPPORTING SAME

(71) Applicant: BIONEVER Inc., Anyang-si (KR)

(72) Inventors: Kyoobom PYUN, Yangpyeong-gun (KR); Dongwan KIM, Hwaseong-si (KR)

(21) Appl. No.: 19/104,352

(22) PCT Filed: Aug. 17, 2023
(86) PCT No.: PCT/KR2023/012208

§ 371 Date: Feb. 17, 2025

(30) Foreign Application Priority Data
Aug. 17, 2022 (KR) 10-2022-0102572

(51) Int. Cl. B60L 53/68; B60L 53/16; B60L 53/30; G01R 31/28

(52) U.S. Cl. CPC B60L 53/68; B60L 53/16; B60L 53/305; G01R 31/2844; B60L 2240/70

(57) ABSTRACT

The present disclosure relates to an electric vehicle charger for remotely performing self-fault diagnosis in an electric vehicle charging system, and the electric vehicle charger includes a communication control module configured to receive a command message for instructing self-fault diagnosis of the electric vehicle charger from a control system and set a test mode for self-fault diagnosis based on the received command message, and a self-fault diagnosis module configured to perform a self-fault diagnosis-related test in a plurality of states of the set test mode to confirm a status of the electric vehicle charger, and transmit a report message including information on the confirmed status of the electric vehicle charger to the communication control module. Thus, the present disclosure has the effect of performing self-fault diagnosis of the status of the electric vehicle charger through remote control.

### TECHNICAL FIELD

The present disclosure relates to an electric vehicle charging system, and more specifically, to a method for remotely performing self-fault diagnosis and a device supporting the same.

### BACKGROUND ART

FIG. 1 is a conceptual diagram illustrating an example of a general electric vehicle charging system.

Referring to FIG. 1, the electric vehicle charging system includes a control system, an electric vehicle charger, and an electric vehicle.

The electric vehicle charging system includes the electric vehicle charger, an electric vehicle, and a control system linked to the electric vehicle charger to support charging of the electric vehicle.

The control system monitors a status of the electric vehicle and a status of the electric vehicle charger. Specifically, the control system may communicate with the electric vehicle charger via open charge point protocol (OCPP).

The electric vehicle charger includes a supply equipment communication controller (SECC) module. The SECC is a communication module included in the electric vehicle charger, and may transmit and receive control information of the electric vehicle charger and status information of the electric vehicle charger to and from the control system based on OCPP communication.

The SECC transmits and receives information related to electric vehicle charging to and from an electric vehicle communication controller (EVCC), which is a control system included in the electric vehicle, through communication based on the ISO 15118 standard.

However, in the case of an electric vehicle charging system of the related art, OCPP provides only a message format for confirmation of status information of an electric vehicle charger, and does not define a procedure and method for confirmation of the status of the electric vehicle charger, especially a procedure and method for confirming what kind of fault the electric vehicle charger has or which part of the electric vehicle charger is faulty.

### DETAILED DESCRIPTION OF INVENTION

### Technical Problems

Therefore, an object of the present disclosure is to provide content for a self-fault diagnosis device capable of self-diagnosing functions inside an electric vehicle charger (even in a situation in which an electric vehicle is not connected) and an operating system that remotely operates the self-fault diagnosis device.

Further, another object of the present disclosure is to provide a method for performing self-fault diagnosis on an electric vehicle charger and a method for determining an error state of the electric vehicle charger.

Further, another object of the present disclosure is to define a new field related to self-fault diagnosis within a message defined in OCPP for self-fault diagnosis.

The objects to be achieved in the present disclosure are not limited to the objects mentioned above, and other objects that have not been mentioned can be clearly understood by those skilled in the art to which the present disclosure belongs from the description below.

### Technical Solution

According to an aspect of the present disclosure, there is a provided an electric vehicle charger for remotely performing self-fault diagnosis in an electric vehicle charging system, the electric vehicle charger including: a communication control module configured to receive a command message for instructing self-fault diagnosis of the electric vehicle charger from a control system and set a test mode for self-fault diagnosis based on the received command message; and a self-fault diagnosis module configured to perform a self-fault diagnosis-related test in a plurality of states of the set test mode to confirm a status of the electric vehicle charger, and transmit a report message including information on the confirmed status of the electric vehicle charger to the communication control module.

Further, in an aspect of the present disclosure, the self-fault diagnosis module includes a charging terminal installed in the self-fault diagnosis module, a charging plug being mated with the charging terminal; an emulator configured to test charging and discharging of the electric vehicle; a voltage and current measurement module configured to measure a voltage and current during a charging test of the electric vehicle; and a variable load module configured to reflect a change in an electric vehicle charging mode.

Further, in an aspect of the present disclosure, the charging terminal is the same as that of the electric vehicle with which the charging plug is mated.

Further, in an aspect of the present disclosure, the variable load module is set to a constant current (CC) mode, a constant power (CP) mode, or a constant voltage (CV) mode.

Further, in an aspect of the present disclosure, the self-fault diagnosis module and the charging plug are connected by a control pilot (CP) line, a proximity pilot (PP) line, a protective earth (PE) line, an AC line, and a DC line.

Further, in an aspect of the present disclosure, the plurality of states are an unmated state, a mated state, an initialized state, a cable check state, a precharge state, a charge state, and a power down state.

Further, in an aspect of the present disclosure, the information on the status of the electric vehicle charger includes information on a normal state or an error state of the electric vehicle charger.

Further, in an aspect of the present disclosure, the unmated state is a state for setting a test mode for testing of the self-fault diagnosis, and the setting of the test mode is a setting of at least one of whether or not high level communication is supported, an identification mode, an authentication and approval mode, a charging mode, a maximum current and voltage acceptable for device safety, a charging test time, a charging energy amount, or an available maximum current.

Further, in an aspect of the present disclosure, the presence or absence of an error in the unmated state is determined by confirming a setting value of the test mode or a voltage of the CP line.

Further, in an aspect of the present disclosure, the mated state is a state for confirming a physical connection of the self-fault diagnosis module, and the presence or absence of an error in the mated state is determined by confirming a voltage of the CP line, a voltage of the PE line, or a voltage of the PP line.

Further, in an aspect of the present disclosure, the initialized state is a state for performing a test for low level communication, and the presence or absence of an error in the initialized state is determined based on whether a signal having a certain ratio of duty cycle is transmitted, a comparison of a DC output voltage with a threshold voltage, and whether a pulse width modulation (PWM) duty cycle matches a maximum allowable current.

Further, in an aspect of the present disclosure, the presence or absence of an error in the cable check state is determined by confirming a voltage of the CP line and based on a result of an insulation test in DC charging.

Further, in an aspect of the present disclosure, the presence or absence of an error in the precharge state is determined based on whether a precharge-related response signal is received, and through a comparison of a DC voltage with a voltage requested by the self-fault diagnosis module.

Further, in an aspect of the present disclosure, the presence or absence of an error in the charge state is determined based on whether a power transfer response signal is transmitted for a certain period of time, whether a charge state response signal is transmitted, or whether AC and DC are transmitted with a predefined amount of power.

Further, in an aspect of the present disclosure, the presence or absence of an error in the power down state is determined based on whether a power transfer response signal is transmitted for a certain period of time, whether a session stop response signal is transmitted, or confirmation of the voltage of the CP line.

Further, in an aspect of the present disclosure, the test result is included in a data transfer request message defined in open charge point protocol (OCPP).

According to another aspect of the present disclosure, there is a provided an electric vehicle charger for remotely performing self-fault diagnosis in an electric vehicle charging system, the electric vehicle charger including: a communication control module configured to communicate with a control system and set a test mode for self-fault diagnosis; and a self-fault diagnosis module, wherein the self-fault diagnosis module periodically performs a self-fault diagnosis-related test in a plurality of states of the set test mode to confirm a state of the self-fault diagnosis module and report an alive message including information on the confirmed state of the self-fault diagnosis module to the communication control module.

Further, in an aspect of the present disclosure, in the confirmation of the state of the self-fault diagnosis module, a read and write process from and to a register included in the self-fault diagnosis module is performed, and when the read and write process is normal, the alive message is generated.

According to still another aspect of the present disclosure, there is a provided a method for remotely performing self-fault diagnosis in an electric vehicle charger in an electric vehicle charging system, the method including: receiving a command message for instructing self-fault diagnosis of the electric vehicle charger from a control system; setting a test mode for self-fault diagnosis based on the received command message; performing a test according to the set test mode to confirm a status of the electric vehicle charger; and transmitting a report message including information on the confirmed status of the electric vehicle charger.

### Effect of Invention

The present disclosure has the effect of being able to self-diagnose the functions inside the electric vehicle charger through remote control (even in a situation where the electric vehicle is not connected).

The effects of the present disclosure are not limited to the effect mentioned above, and other effects that have not been mentioned can be clearly understood by those skilled in the art from the description below.

### BRIEF DESCRIPTION OF THE DRAWING

The accompanying drawings, which are included as part of the detailed description to help understanding of the present disclosure, provide examples of the present disclosure and explain the technical characteristics of the present disclosure together with the detailed description.

FIG. 1 is a conceptual diagram illustrating an example of a general electric vehicle charging system.

FIG. 2 is a conceptual diagram illustrating an example of an electric vehicle charging system proposed in the present disclosure.

FIG. 3 shows still another internal block diagram of the electric vehicle charger proposed in the present disclosure.

FIG. 4 is a diagram illustrating an example of various types of connectors that may be used for self-fault diagnosis proposed in the present disclosure.

FIG. 5 is a diagram illustrating an example of an internal block diagram of a self-fault diagnosis device proposed in the present disclosure.

FIG. 6 is a diagram illustrating an example of an interface of the self-fault diagnosis device proposed in the present disclosure.

FIG. 7 is a diagram illustrating an example of an internal block diagram or internal circuit diagram of the self-fault diagnosis device proposed in the present disclosure.

FIG. 8 illustrates an example of a pilot line voltage that can be applied to a method proposed in the present disclosure.

FIG. 9 illustrates an example of an internal block diagram of the electric vehicle charger that performs self-fault diagnosis through remote control in an electric vehicle charging system proposed in the present disclosure.

FIG. 10 is a flowchart showing a method for performing self-fault diagnosis in the electric vehicle charger through remote control in the electric vehicle charging system proposed in the present disclosure.

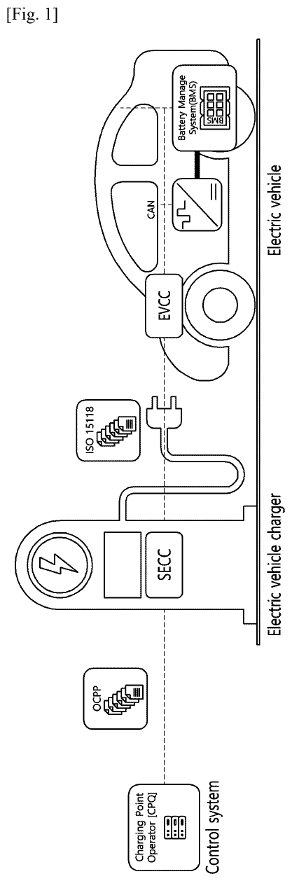

### BEST MODE FOR CARRYING OUT THE INVENTION

It should be noted that the technical terms used in the present disclosure are used only to describe specific embodiments and are not intended to limit the spirit of the technology disclosed in the present disclosure. Further, the technical terms used in the present disclosure should be interpreted as meanings generally understood by those skilled in the art to which the technology disclosed in the present disclosure belongs, unless specifically defined otherwise in the present disclosure, and should not be interpreted in an excessively comprehensive or excessively narrow sense. Further, when the technical terms used in the present disclosure are incorrect technical terms that do not accurately express the spirit of the technology disclosed in the present disclosure, the technical terms should be replaced with technical terms that can be correctly understood by those skilled in the art to which the technology disclosed in the present disclosure belongs. Further, the general terms used in the present disclosure should be interpreted according to their definitions in the dictionary or according to the context, and should not be interpreted in an excessively narrow sense.

Terms including ordinal numbers such as first and second used in the present disclosure may be used to describe various components, but the components should not be limited by the terms. The terms are used only for the purpose of distinguishing one component from another. For example, a first component may be referred to as a second component, and similarly, a second component may also be referred to as a first component without departing from the scope of the present disclosure.

Hereinafter, embodiments disclosed in the present disclosure will be described in detail with reference to the accompanying drawings, and the same or similar components will be denoted by the same reference signs regardless of drawing symbols, and redundant descriptions thereof will be omitted.

Further, when it is determined that detailed description of a related known technology may obscure the gist of the technology disclosed in the present disclosure in describing the technology disclosed in the present disclosure, the detailed description will be omitted. Further, it should be noted that the accompanying drawings are only intended to facilitate understanding of the spirit of the technology disclosed in the present disclosure, and should not be construed as limiting the spirit of the technology.

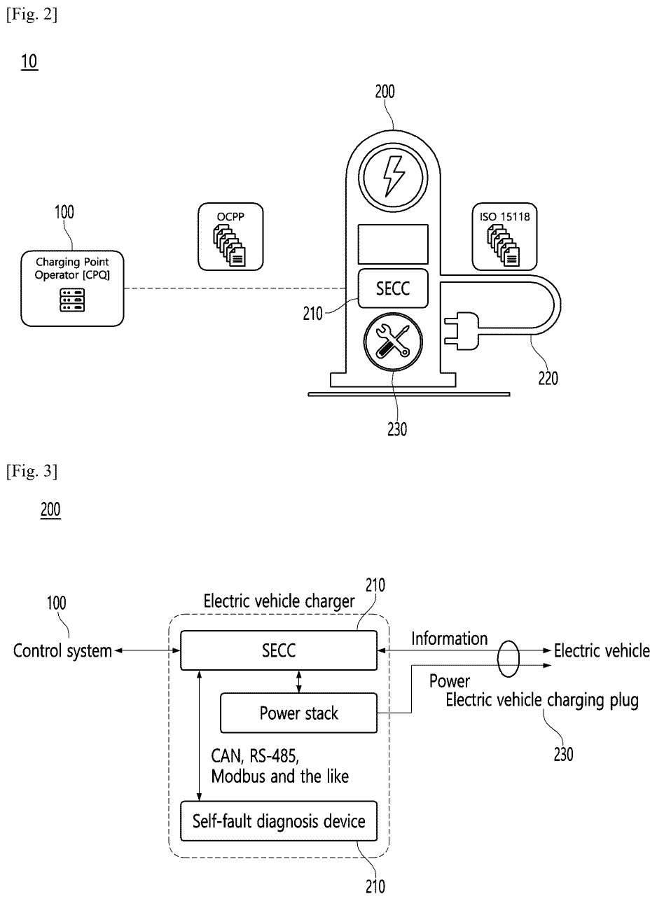

FIG. 2 illustrates an example of a conceptual diagram of an electric vehicle charging system proposed in the present disclosure.

That is, the present disclosure provides an electric vehicle charging system capable of remotely monitoring a status of an electric vehicle charger and diagnosis of failure through a control system.

Referring to FIG. 2, an electric vehicle charging system 10 proposed in the present disclosure may include a control system 100, and an electric vehicle charger 200 including a self-fault diagnosis device 230. The self-fault diagnosis device may be configured as an embedded system in the electric vehicle charger.

The self-fault diagnosis device 230 is an emulator for diagnosing whether the electric vehicle charger is faulty, and may be briefly referred to as an emulator, an electric vehicle emulator, a self-fault diagnosis module, or the like.

The self-fault diagnosis device may communicate with an SECC 210 included in the electric vehicle charger, or may communicate directly with the control system. The self-fault diagnosis device may communicate with the SECC through various schemes such as a controller area network (CAN), RS-485, and Modbus.

FIG. 3 shows another internal block diagram of the electric vehicle charger proposed in the present disclosure.

Referring to FIG. 3, it can be seen that the self-fault diagnosis device and the SECC are connected through communication using CAN, RS-485, Modbus, or the like, and the SECC is connected to the electric vehicle through communication with the control system and an electric vehicle charging plug.

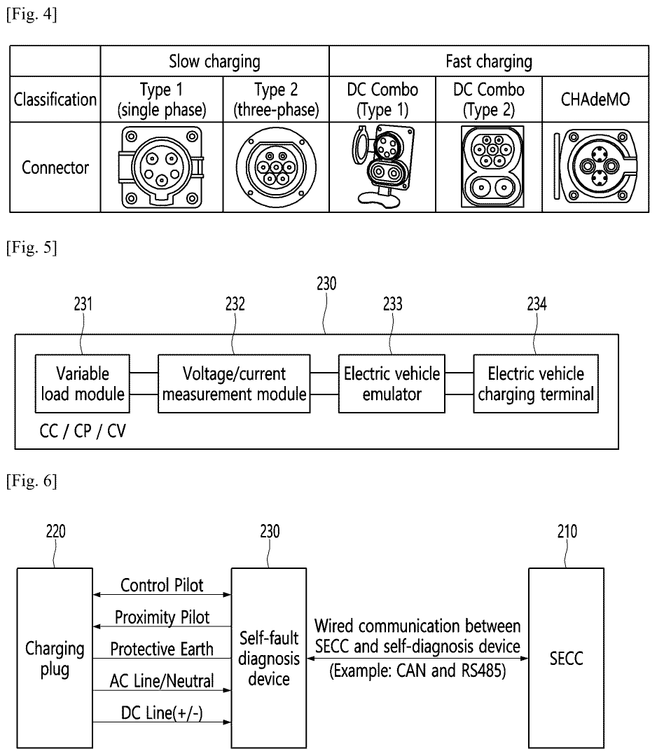

The self-fault diagnosis device is an electric vehicle emulator for performing fault diagnosis of the electric vehicle charger, and an external terminal of the self-fault diagnosis device may be configured as an external terminal that is the same as an electric vehicle charging terminal 220, so that the electric vehicle charging plug can be connected, mated, or plugged into the external terminal. The external terminal of the self-fault diagnosis device can support all of various types of connectors as illustrated in FIG. 4.

FIG. 4 is a diagram illustrating examples of various types of connectors that may be used for the self-fault diagnosis proposed in the present disclosure.

As illustrated in FIG. 4, the connectors may be classified into slow charging connectors and fast charging connectors, the slow charging connectors may be classified into Type 1 corresponding to a single phase and Type 2 corresponding to a three-phase, and the fast charging connectors may be classified into DC Combo (Type 1), DC Combo (Type 2), and CHAdeMO.

Returning to the content described in FIG. 2, the control system monitors electric vehicle charger status information and electric vehicle status information through the OCPP protocol.

That is, the control system may receive the electric vehicle charger status information from the electric vehicle charger through the transmission and reception of messages defined in the OCPP protocol to and from the electric vehicle charger.

Tables 1 to 3 below are tables showing examples of message formats newly defined for transmission and reception of the electric vehicle charger status information between the control system proposed in the present disclosure and the electric vehicle charger through the OCPP protocol.

First, Table 1 shows an example in which related fields are newly defined in a status notification request (StatusNotification.Req) message defined in OCPP 1.6 to support status information of the electric vehicle charger proposed in the present disclosure.

That is, in order to transmit and receive the status information of the electric vehicle charger between the control system and the electric vehicle charger, a status field, a vendor identifier field (vendorId field), and a vendor error code field (vendorErrorCode field) may be newly defined in the status notification request message defined in OCPP 1.6 as shown in Table 1.

TABLE 1

| Field name | Field type | Card | Description |
|---|---|---|---|
| connectorId | Integer | 1 . . . 1 | Required. The id of |
| | | | the connector for |
| | | | which the status is |
| | | | reported. Id ‘0’(zero |
| | | | is used when the |
| | | | status for the Charge |
| | | | Point main |
| | | | controller |
| errorCode | ChargePointErrorCode | 1 . . . 1 | Required. This |
| | | | contains the error |
| | | | code reported by the |
| | | | Charge Point |
| Info | Cistring50Type | 0 . . . 1 | Optional. Additional |
| | | | free format |
| | | | information related |
| | | | to the error |
| Status | ChargePointStatus | 1 . . . 1 | Required. This |
| | | | contains the current |
| | | | status of the Charge |
| | | | Point |
| Timestamp | dateTime | 0 . . . 1 | Optional. The time |
| | | | for which the status |
| | | | is reported. When |
| | | | absent time of |
| | | | receipt of the |
| | | | message will be |
| | | | assumed. |
| vendorId | CiString255Type | 0 . . . 1 | Optional. This |
| | | | identifies the |
| | | | vendor-specific |
| | | | implementation. |
| vendorErrorCode | CiString50Type | 0 . . . 1 | Optional. This |
| | | | contains the vendor- |
| | | | specific error code. |

In Table 1, the vendorId field and the vendorErrorCode field are available fields already defined by a charger manufacturer, and may be used to transmit diagnosis results of the electric vehicle charger to a CMS. Here, since the card is 0 . . . 1, the field may contain up to one value.

Next, Table 2 shows an example in which related fields are newly defined in a data transfer request (DataTransfer.Req) message defined in OCPP 1.6 to support the status information of the electric vehicle charger proposed in the present disclosure.

That is, as shown in Table 2, messageId and data field according to a result of diagnosing the status of the electric vehicle charger are newly defined in the data transfer request (DataTransfer.Req) message, and DataTransfer. Req including the result of diagnosing the status of the electric vehicle charger may be transmitted to the CMS.

TABLE 2

| Field name | Field type | Card | Description |
|---|---|---|---|
| vendorId | CiString255Type | 1 . . . 1 | Required. This |
| | | | identifies the |
| | | | vendor-specific |
| | | | implementation |
| messageId | Cistring50Type | 0 . . . 1 | Optional. |
| | | | Additional |
| | | | identification field |
| data | Text Length | 0 . . . 1 | Optional. Data |
| | undefined | | without specified |
| | | | length or format |

Further, a message defined in OCPP 2.0 and OCPP 2.0.1 may also be used for the transfer of the status information of the electric vehicle charger. However, since the purpose of the status notification request message (StatusNotification.Req) defined in OCPP 1.6 has been changed in OCPP 2.0 and OCPP 2.0.1, the status notification request message cannot be used as in OCPP 1.6, but the status information of the electric vehicle charger may be transferred through the data transfer request (DataTransfer.Req) message defined in OCPP 2.0 and OCPP 2.0.1.

That is, Table 3 shows an example in which related fields are newly defined in the data transfer request (DataTransfer.Req) message defined in OCPP 2.0 and OCPP 2.0.1 to 10 support the status information of the electric vehicle charger proposed in the present disclosure.

TABLE 3

| Field name | Field type | Card | Description |
|---|---|---|---|
| messageId | String[0 . . . 50] | 0 . . . 1 | Optional. May be used to |
| | | | indicate a specific message or |
| | | | implementation. |
| data | anyType | 0 . . . 1 | Optional. Data without |
| | | | specified length or |
| | | | format. This needs to be |
| | | | decided by both parties |
| | | | (Open to implementation). |
| vendorId | String[0 . . . 255] | 1 . . . 1 | Required. This identifies the |
| | | | vendor-specific |
| | | | implementation. |

As shown in Tables 1 to 3, it may be desirable to transmit and receive status information related to whether or not the electric vehicle charger normally operates, by utilizing the data transmission request (DataTransfer.Req) message that can be simultaneously utilized in OCPP 1.6, OCPP 2.0, and OCPP 2.0.1.

FIG. 5 is a diagram illustrating an example of an internal block diagram of the self-fault diagnosis device proposed in the present disclosure.

Referring to FIG. 5, the self-fault diagnosis device 230 may include a variable load module 231, a voltage/current measurement module 232, an electric vehicle emulator 233, and an electric vehicle charging terminal (or an electric vehicle charging socket) 234.

As described above, the electric vehicle charging terminal or socket 234 may be configured in the same form as an external terminal of the electric vehicle.

The electric vehicle emulator 233 is configured as an electric vehicle modeling system for testing electric vehicle charging and/or discharging. In particular, the electric vehicle emulator may model characteristics such as 20% and 80% of battery's remaining energy virtually in order to model an electric vehicle battery state.

The voltage/current measurement module (or, metering module) is configured as an element for measuring a voltage and current in an electric vehicle charging test.

The variable load module (or final load stage) may be configured as a variable load so that change to a constant current (CC)/constant power (CP)/constant voltage (CV) mode is performed to reflect change in an electric vehicle charging mode.

Next, a method for performing a diagnosis of the electric vehicle charger through the self-fault diagnosis device will be specifically described.

After the electric vehicle charger is used, the electric vehicle charging terminal may be connected to an external terminal of the self-fault diagnosis device or may be mounted on a holder connected to the electric vehicle charger.

Thereafter, the control system requests the electric vehicle charger to perform self-fault diagnosis periodically or according to user settings. In this case, the control system instructs the electric vehicle charger (or SECC) to perform self-fault diagnosis through the data transfer request (DataTransfer.Req) message defined in OCPP 1.6, OCPP 2.0, and OCPP2.01 as shown in Tables 1 to 3. The SECC requests the self-fault diagnosis device and the electric vehicle charger to perform a presetting for fault diagnosis according to the instructed fault diagnosis.

Thereafter, when the presetting for the fault diagnosis is completed, the electric vehicle charger applies a signal for charging and/or discharging the electric vehicle to the self-fault diagnosis device.

Thereafter, the self-fault diagnosis device performs diagnosis of the status of the electric vehicle charger according to a procedure to be described below.

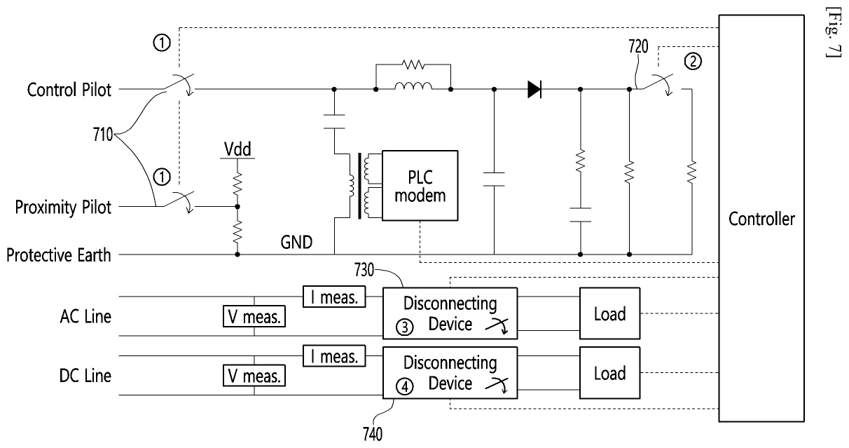

FIG. 6 is a diagram illustrating an example of an interface of the self-fault diagnosis device proposed in the present disclosure, and FIG. 7 shows an example of an internal block diagram or internal circuit diagram of the self-fault diagnosis device proposed in the present disclosure.

Referring to FIGS. 6 and 7, the self-fault diagnosis device 230 is connected to the charging plug 220 and the SECC 210.

That is, the self-fault diagnosis device performs upper layer communication and lower layer communication through a control pilot (CP), and a controller and a modem are connected to a CP line for CP state control.

A module capable of measuring voltage/current is connected to an AC/DC line.

The controller sets and operates the self-fault diagnosis device according to the test mode set by the SECC via CAN communication. The controller reports a modem transmission/reception status and a voltage/current measurement value of the AC/DC line to the SECC according to the test mode. Alternatively, the controller distinguishes between a normal state and an error state based on measurement values measured by the controller and reports these to the SECC.

Table 4 below shows examples of vehicle states according to an internal connection status of the self-fault diagnosis device in FIG. 7.

TABLE 4

| Vehicle | Connected | charging | Pilot line | | |
|---|---|---|---|---|---|
| state | vehicle | available | voltage | | |
| state A | No | No | 12 | V | |
| state B | Yes | No | 9 | V | |
| state C | Yes | Vehicle ready | 6 | V | Charging area |
| | | | | | ventilation not |
| | | | | | required |
| state D | Yes | Vehicle ready | 3 | V | Charging area |
| | | | | | ventilation |
| | | | | | required |
| state E | Yes | No | 0 | V | |
| state F | Yes | No | −12 | V | Power supply |
| | | | | | unavailable |

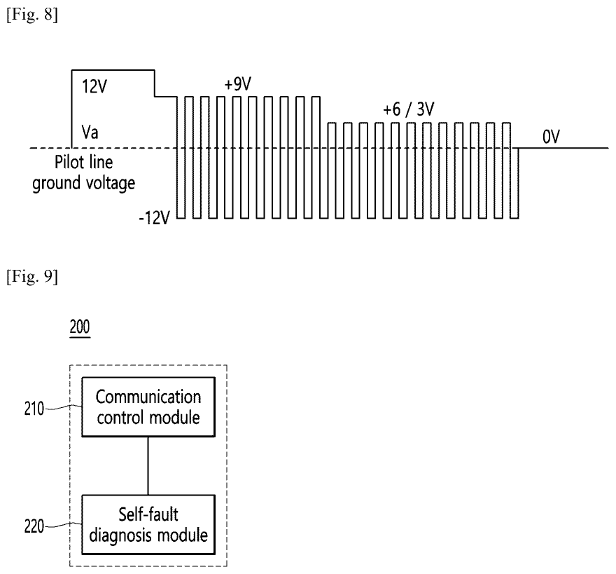

In Table 4, the charging area ventilation not required in state C or the charging area ventilation required in state D is set according to an instruction of an upper layer (or upper level), and the self-fault diagnosis device changes the state based on a value indicated by the upper layer. FIG. 8 illustrates an example of the pilot line voltage that can be applied to the method proposed in the present disclosure. That is, FIG. 8 is a diagram schematically illustrating the pilot line voltage shown in Table 4.

The diagnosis of the self-fault diagnosis device may be performed corresponding to a charging sequence step. Therefore, the diagnosis performed by the self-fault diagnosis device may be performed in the unmated state, the mated state, the initialized state, the cable check state, the precharge state, the charge state, and the power down state.

The states of Table 4 will be described in more detail with reference to FIG. 7.

State A is a state in which the charging plug is not connected to the self-fault diagnosis device or the charging plug is not placed on the holder, and charging is not available, the pilot line voltage indicates 12 V, and state A may correspond to the unmated state.

State B is a state in which a first switch 710 in FIG. 7 is closed, is a state in which the charging plug is connected to the self-fault diagnosis device or the charging plug is placed on the holder, but charging is not available yet, and the pilot line voltage indicates 9 V, which is lower than 12 V.

State C or state D is a state in which the first switch 710 and a second switch 720 in FIG. 7 are closed, and charging is available, and the pilot line voltages are further lowered to 6 V or 3 V, respectively. State C does not require ventilation in the charging area, and state D requires ventilation in the charging area.

State E or state F is a state in which the charging plug is connected to the self-fault diagnosis device or the charging plug is placed on the holder, but charging is not available, and the pilot line voltage indicates 0 V or −12 V, and state F indicates a state in which the power supply is not available.

The self-fault diagnosis device performs a fault diagnosis on the status of the electric vehicle charger in the unmated state, the mated state, the initialized state, cable check state, the precharge state, the charge state, and the power down state through test modes of (1) communication path and register control test, (2) physical connection test, (3) low level communication test, and (4) charging session test when mating of the charging plug is detected.

A case in which the mating of the charging plug is detected may be a case in which the charging plug is connected or mated with the self-fault diagnosis device, or a state in which the charging plug is connected or mated with the holder of the self-fault diagnosis device.

Hereinafter, a method for performing a self-fault diagnosis in each of a plurality of states according to the test mode in the self-fault diagnosis device will be described in more detail with reference to FIGS. 6 to 8.

### Communication Path and Register Control Test

First, the communication path and register control test (hereinafter referred to as “first test”) performed by the self-fault diagnosis device will be described.

The first test is a process of setting the test in the above-described unmated state.

First, the control system sets the test mode through the SECC for diagnosis of the electric vehicle charger through OCPP communication. The first test may be performed in state A of Table 4.

The test mode may be set on the electric vehicle charger side and the self-fault diagnosis device side.

### Electric Vehicle Charger Side Setup

Whether to support high level communication

Identification, authentication/approval mode

Charging mode: AC and DC (only AC can be selected when high level communication is not supported)

Maximum power that can be supplied

Self-Fault Diagnosis Device Side (that is, Electric Vehicle Side) Setup

Whether high level communication is supported

Identification mode: Plug&Charge (PnC; connection recognition and automatic charging), and external identification (EIM; external identification means)

Authentication/approval mode: This is performed in an electric vehicle power supply, and may be performed with the aid of an auxiliary actuator

Charging mode: AC and DC (only AC can be selected when high level communication is not supported)

Maximum current/voltage acceptable for device safety

Charging test time

Amount of energy for charging: Energy required for the electric vehicle until an electric vehicle departure time is reached, or energy with which a state of charge (SOC) value of a battery becomes 100%

Maximum current that can be provided by the power supply: To determine the presence or absence of an error in a pilot duty cycle that is provided by the power supply in an AC charging mode

Thereafter, the SECC sets the test mode of the self-fault diagnosis device for diagnosis of the status of the electric vehicle charger through wired communication (for example, CAN communication, RS-485, or Modbus) between the SECC and the self-fault diagnosis device.

In the first test, since the first switch (see 7 in FIG. 71) in the internal block diagram of the self-fault diagnosis device is open, the CP of the electric vehicle charger is in state A (pilot line voltage: +12 V) in Table 4.

Thereafter, the control system transmits a command to start the diagnosis to the SECC of the self-fault diagnosis device through OCPP communication. In this case, messages and fields corresponding to Tables 1 to 3 may be used.

Next, a method for determining an error occurring in the first test will be described. When at least one of the following descriptions is satisfied, it may be determined that an error occurs.

The control system sets the test mode in the SECC and then confirms a value for the set test mode, and when it is confirmed that contents do not match, the control system determines that an OCPP communication error occurs.

The SECC sets the test mode in the self-fault diagnosis device and then confirms a set value, and when it is confirmed that contents do not match, the SECC determines that a communication error between the SECC and the self-fault diagnosis device occurs.

When the state of the CP controller of the electric vehicle charger is not state A (pilot line voltage: +12 V) in Table 4, the SECC determines that an error occurs in the state of the CP controller.

### Physical Connection Test

Next, a method for performing a physical connection test (hereinafter referred to as a “second test”) that is performed by the self-fault diagnosis device will be described.

The second test is a process of confirming a connection state of a physical device in the above-described mated state.

First, the self-fault diagnosis device which has received a command from the control system to start the diagnosis closes switch 1 in FIG. 7.

In this case, a voltage of the CP line of the SECC is reduced from 12 V to 9 V, and a state of the CP controller of the electric vehicle charger is changed from state A to state B in Table 4.

The SECC checks a proximity earth (PE) ground and a proximity pilot (PP) voltage.

A method for determining an error occurring in the physical connection test is as follows. When at least one of the following descriptions is satisfied, it may be determined that an error occurs.

First, when the state of the CP controller of the electric vehicle charger is not changed to state B, the SECC determines that an error occurs in the state of the CP controller.

When 0 V is not recognized in the PE line, the SECC determines that an error occurs in the PE line.

When the voltage is not recognized in the PP line, the SECC determines that an error occurs in the PP line.

### Lower Level Communication Test

Next, a low level communication test (hereinafter referred to as a “third test”) method that is performed in the self-fault diagnosis device will be described.

The third test is performed in the initialized state described above, a matching processor starts through low level communication in the CP line, and a specific procedure is as follows.

First, the CP controller of the electric vehicle charger starts communication with a duty cycle of 5%.

Here, a procedure of a diagnosis mode is distinguished depending on whether the self-fault diagnosis device supports the upper layer communication, and the diagnosis mode when the upper layer communication is not supported (AC charging available) is performed as follows.

The self-fault diagnosis device does not respond to the duty cycle of 5%.

The self-fault diagnosis device maintains the CP state as state E/state F during T_step_EF.

In order to perform the diagnosis of the status of the electric vehicle charger according to the KS C IEC 61851-1 standard, the electric vehicle charger sets a valid duty cycle in the range of 10% to 96%.

Next, when the upper layer communication is supported (AC and DC charging is available), the diagnosis mode is performed as follows.

First, a matching processor for exchanging charging parameters is performed.

Thereafter, the status of the electric vehicle charger is switched to “matching” (logical network connection success), a D-LINK_READY.indication (link setting completion) indicating matching success or matching failure is transmitted to the upper layer, and then the status of the electric vehicle charger is switched to “matched”.

In the case of DC charging, the electric vehicle charger itself may diagnose a voltage of a DC power line.

A method for determining an error occurring in the third test, that is, a low level communication test, is as follows. When at least one of the following descriptions is satisfied, it may be determined that an error occurs.

First, the self-fault diagnosis device determines that a 5% duty PWM error occurs when the electric vehicle charger does not transmit a signal with the duty cycle of 5% even after a certain period of time has elapsed or when the duty of the signal deviates from (5±margin) %.

When an error occurs during the matching process in both the self-fault diagnosis device and the SECC and the status of the electric vehicle charger is a “Unmatched” state, the matching process is determined to have failed.

In the case of DC charging, when a DC output voltage provided by the electric vehicle charger is higher than a specific voltage (for example, 60 V), the SECC determines that there is a maximum DC supply voltage error.

The self-fault diagnosis device determines that an AC charging error occurs when an electric vehicle charger for AC charging does not change a PWM duty cycle to 10% to 96% or when the PWM duty cycle does not match a maximum allowable current.

### Charging Session Test

Next, a charging session test (hereinafter referred to as a “fourth test”) that is performed by the self-fault diagnosis device will be described.

The fourth test includes a cable check state, a precharge state, a charge state, and a power down state, and a diagnostic procedure that is performed in each state will be described.

In the fourth test, electric vehicle charging is prepared after the matching processor of the third test is ended in the cable check state, and communication setting, identification/authentication/approval, target setting, and charging scheduling are performed.

### Cable Check State

First, communication is established. This means performing an IP-based access connection.

A data link is established. This means performing set identification, identification according to an authentication/approval mode, and an authorization/approval process.

Vehicle-to-grid (V2G) setup for setting a charging target and scheduling is performed.

The self-fault diagnosis device closes the second switch 720 in FIG. 7 to change the CP line state to state C (or state D) in Table 4. Both state C and state D are states in which energy can be received in the self-fault diagnosis device.

In state C, the CP line is at +6 V, and in state D, the CP line is at +3 V.

In the case of DC charging, the self-fault diagnosis device transmits a cable check request (CableCheckReq) message to the electric vehicle charger to request a cable check.

The electric vehicle charger checks the isolation with an electric vehicle HV system, and then sets or includes a result of the check in a cable check response (CableCheckRes) message to transmit the cable check response message to the self-fault diagnosis device.

A method for determining an error in the cable check state is as follows.

When at least one of the following descriptions is satisfied, it may be determined that an error occurs.

When there is no correct association between the electric vehicle charger (or power supply communication controller) and the self-fault diagnosis device in both the self-fault diagnosis device and the SECC or a timeout occurs in a mating process, it is determined that a high level communication establishment fails and an error occurs.

When the CP state does not change from state B to state C or state D, the SECC determines that there is a CP line error.

In a case in which both the self-fault diagnosis device and the SECC adopt DC charging, it may be determined that an isolation error occurs when there is an error in an insulation test or when a cable check (CableCheck) result included in the cable check request (CableCheckRes) message is not “Valid”.

### Precharge State

A test procedure in the precharge state (only in the case of DC charging) is as follows.

First, the emulator starts a precharge process by sending a precharge request (PreChargeReq) message.

The switch is closed so that the electric vehicle charger can supply power. That is, a contactor on the electric vehicle charger side is closed.

A DC supply of the electric vehicle charger applies a voltage request through the precharge request (PreChargeReq) message in an allowable maximum current range.

The self-fault diagnosis device monitors a voltage in a DC supply line.

When a difference between a battery voltage set in the self-fault diagnosis device and the DC supply line voltage is less than 20 V, a disconnection device (a third switch 730 in FIG. 7) of the self-fault diagnosis device is closed.

A method for determining an error in the precharge state is as follows.

When at least one of the following descriptions is satisfied, it may be determined that an error has occurred.

The self-fault diagnosis device determines a reception error for a precharge response (PreChargeRes) signal.

Further, the self-fault diagnosis device determines that a DC voltage error has occurred when a DC voltage transmitted from the electric vehicle charger is not a voltage requested by the self-fault diagnosis device.

### Charge State

Next, a method for testing in the charge state will be described.

First, the self-fault diagnosis device transmits a power delivery request (PowerDeliveryReq) message.

In the case of AC charging, the self-fault diagnosis device closes the disconnection device (a fourth switch 740 in FIG. 7), and the electric vehicle charger also closes the contactor on the electric vehicle charger side. In other words, the switch is closed so that the electric vehicle charger can supply power.

The electric vehicle charger transmits a power delivery response (PowerDeliveryRes) message when energy transfer becomes possible.

In the case of DC charging, a voltage/current supplied from the electric vehicle charger is controlled through a current demand request/response (CurrentDemandReq/Res) message.

In the case of AC charging, charging control and rescheduling are performed through a charging status request/response (ChargingStatusReq/Res) message.

The electric vehicle charger transmits energy, and the self-fault diagnosis device monitors the transmitted voltage/current.

### Charge State

Next, a method for determining an error in the charge state will be described. When at least one of the following descriptions is satisfied, it may be determined that the error occurs.

The self-fault diagnosis device determines that an error occurs when the electric vehicle charger does not transmit the power delivery response (PowerDeliveryRes) message within a predetermined time.

The self-fault diagnosis device determines that an error occurs when the electric vehicle charger does not transmit a CurrentDemandRes/ChargingStatusRes message within a predetermined time.

The self-fault diagnosis device determines that an error occurs when the AC/DC is not delivered at a negotiated power amount.

The self-fault diagnosis device determines that an error occurs when AC or DC power is not delivered due to a contactor failure.

### Power Down State

Next, a metho of a test in the power down state will be described.

First, the self-fault diagnosis device transmits the power delivery request (PowerDeliveryReq) message when set “charging test time” has elapsed after the charging test starts. In other words, the self-fault diagnosis device transmits a message indicating an energy transmission completion request.

In the case of AC charging, the self-fault diagnosis device changes the CP to state B and opens the disconnection device, and the electric vehicle charger opens the contactor.

The electric vehicle charger sets a “Not Ready” state value and responds with the power delivery response (PowerDeliveryRes) message.

In the case of DC charging, the electric vehicle charger reduces a current to 1 A or less.

The self-fault diagnosis device opens the disconnection device after the current is reduced to 1 A or less.

The electric vehicle charger disables an output voltage and opens the contactor, and the electric vehicle charger sets the “Not Ready” state value to respond with the power delivery response (PowerDeliveryRes) message.

The self-fault diagnosis device opens the second switch 720 in FIG. 7 to change the CP to state B.

The self-fault diagnosis device requests the termination of PLC communication through a session stop request (SessiontStopReq) message.

The electric vehicle charger responds with a session stop response (SessionStopRes) message.

The self-fault diagnosis device opens the first switch 710 in FIG. 7 to change the CP to state A.

The method for determining an error occurring in the power down state is as follows. When at least one of the following descriptions is satisfied, it may be determined that an error occurs.

The self-fault diagnosis device determines that an error occurs when the electric charger does not transmit the power delivery response (PowerDeliveryRes) message within a predetermined time.

The SECC determines that an error occurs when the CP state is not changed (or converted) to state B.

The self-fault diagnosis device determines that an error occurs when the charger does not transmit a session stop response (SessionStopRes) message within a predetermined time.

The SECC determines that an error occurs when the CP state is not converted to state A.

FIG. 9 illustrates an example of an internal block diagram of the electric vehicle charger that performs self-fault diagnosis through remote control in the electric vehicle charging system proposed in the present disclosure.

The electric vehicle charger 200 may include a communication control module 210 and a self-fault diagnosis module 220 to perform self-fault diagnosis through remote control.

The communication control module may be the SECC described above.

The communication control module receives from the control system a command message for instructing self-fault diagnosis of the electric vehicle charger, and sets the test mode for self-fault diagnosis based on the received command message.

Further, the self-fault diagnosis module performs a self-fault diagnosis-related test in the plurality of states of the test mode set by the communication control module to confirm the status of the electric vehicle charger and transmit a report message including information on the confirmed status of the electric vehicle charger to the communication control module.

The plurality of states may be the unmated state, the mated state, the initialized state, the cable check state, the precharge state, the charge state, and the power down state.

Further, information on the status of the electric vehicle charger may include information on a normal state or an error state of the electric vehicle charger.

Further, the test result may be included in a data transfer request message defined in open charge point protocol (OCPP).

The self-fault diagnosis module may include a charging terminal, an emulator, a voltage and current measurement module, and a variable load module, as illustrated in FIG. 5.

First, the charging terminal is installed in the self-fault diagnosis module, and a charging plug may be mated with the charging terminal, and the charging terminal may be the same as the charging terminal of the electric vehicle with which the charging plug is mated.

The emulator tests charging and discharging of the electric vehicle.

The voltage and current measurement module measures a voltage and current during a charging test for the electric vehicle.

The variable load module is intended to reflect a change in the electric vehicle charging mode, and may be set to a constant current (CC) mode, a constant power (CP) mode, or a constant voltage (CV) mode.

Referring to FIG. 6, the self-fault diagnosis module may be connected to the charging plug, a control pilot (CP) line, a proximity pilot (PP) line, a protective earth (PE) line, an AC line, and a DC line.

The self-fault diagnosis module may perform a test for each state in the test mode and determine whether the electric vehicle charger is in the normal state or the error state in each state.

First, the unmated state is a state for setting a test mode for testing of the self-fault diagnosis.

Here, for the setting of the test mode, at least one of whether or not high level communication is supported, an identification mode, an authentication and approval mode, a charging mode, a maximum current and voltage acceptable for device safety, a charging test time, a charging energy amount, and a maximum current that can be provided may be set.

In the unmated state, the presence or absence of an error may be determined by confirming a setting value of the test mode or confirming the voltage of the CP line.

Further, the mated state is a state for confirming a physical connection of the self-fault diagnosis module. In the mated state, the presence or absence of an error may be determined by confirming the voltage of the CP line, the voltage of the PE line, or the voltage of the PP line.

Further, the initialized state is a state for performing a test for low level communication. In the initialized state, the presence or absence of an error may be determined based on whether a signal having a certain ratio of duty cycle is transmitted, a comparison of the DC output voltage with a threshold voltage, and whether a pulse width modulation (PWM) duty cycle matches the maximum allowable current.

Further, the presence or absence of an error in the cable check state may be determined by confirming the voltage of the CP line and based on a result of an insulation test in the DC charging.

Further, the presence or absence of an error in the precharge state may be determined based on whether a precharge-related response signal is received, and through comparison of the DC voltage with a voltage requested by the self-fault diagnosis module.

Further, the presence or absence of an error in the charge state may be determined based on whether the power transfer response signal is transmitted for a certain period of time, whether there is a charge state response signal transmitted, or whether AC and DC are transmitted with a predefined amount of power.

Further, the presence or absence of an error in the power down state may be determined based on whether a power transfer response signal is transmitted for a certain period of time, whether a session stop response signal is transmitted, or confirmation of the voltage of the CP line.

In another embodiment, according to the present disclosure, the fault diagnosis may be performed by the self-fault diagnosis device on its own, and a specific method is as follows.

The self-fault diagnosis module included in the electric vehicle charger may periodically perform the self-fault diagnosis-related test in the plurality of states of the test mode set by the communication control module to confirm the state of the self-fault diagnosis module and report an alive message including information on the confirmed state of the self-fault diagnosis module to the communication control module.

Here, in the confirmation of the state of the self-fault diagnosis module, a read and write process from and to a register included in the self-fault diagnosis module may be performed, and when the read and write process is normal, the alive message may be generated.

A specific procedure for performing a fault diagnosis in each state described above and whether an error is determined will refer to the above-described content.

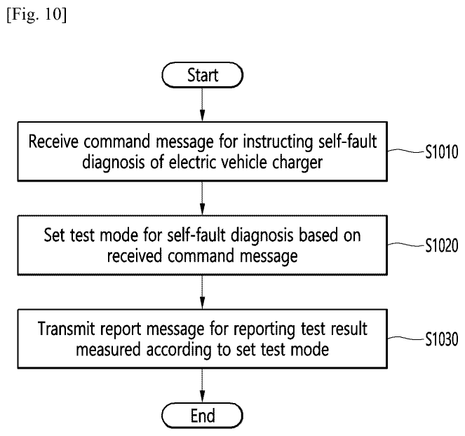

FIG. 10 is a flowchart showing a method for remotely performing self-fault diagnosis on the electric vehicle charger in the electric vehicle charging system proposed in the present disclosure.

First, the electric vehicle charger receives the command message for instructing self-fault diagnosis of the electric vehicle charger from the control system (S1010).

The electric vehicle charger sets the test mode for self-fault diagnosis based on the received command message (S1020).

The electric vehicle charger transmits a report message for reporting a test result measured according to the set test mode to the control server (S1030).

The test result may include the status information of the electric vehicle charger, and the status information of the electric vehicle charger may include the information on the normal state or the error state of the electric vehicle charger.

The embodiments described above are combinations of components and characteristics of the present disclosure in a predetermined form. Each component or characteristic should be considered optional unless otherwise explicitly stated. Each component or characteristic may be implemented in a form in which there is no combination with other components or characteristics. Further, it is also possible to configure the embodiment of the present disclosure by combining some components and/or characteristics. An order of operations described in the embodiments of the present disclosure may be changed. Some components or characteristics of a certain embodiment may be included in another embodiment, or may be replaced with corresponding components or characteristics of another embodiment. It is obvious that claims that do not have an explicit citation relationship in the claims may be combined to form an embodiment or included as new claims by amendment after filing.

The embodiments according to the present disclosure may be implemented by various means, for example, hardware, firmware, software, or a combination thereof. When the embodiment of the present disclosure is implemented by the hardware, an embodiment of the present disclosure may be implemented by one or more application specific integrated circuits (ASICs), digital signal processors (DSPs), digital signal processing devices (DSPDs), programmable logic devices (PLDs), field programmable gate arrays (FPGAs), processors, controllers, microcontrollers, microprocessors, or the like.

When the embodiment of the present disclosure is implemented by the firmware or the software, the embodiment of the present disclosure may be implemented in the form of a module, procedure, function, or the like that performs the functions or operations described above. Software code may be stored in a memory and driven by a processor. The memory may be located inside or outside the processor and may exchange data with the processor by various means already known.

It will be obvious to those skilled in the art that the present disclosure can be embodied in other specific forms without departing from essential characteristics of the present disclosure. Therefore, the detailed description described above should not be construed as limiting in all aspects and should be considered as illustrative. The scope of the present disclosure should be determined by a reasonable interpretation of the appended claims, and all changes within the equivalent scope of the present disclosure are included in the scope of the present disclosure.

### INDUSTRIAL APPLICABILITY

Although a case in which the method for remotely performing self-fault diagnosis in the electric vehicle charging system of the present disclosure is applied to the electric vehicle has been described by way of example, the method can be applied to various other systems.

1. An electric vehicle charger for remotely performing self-fault diagnosis in an electric vehicle charging system, the electric vehicle charger comprising:
a communication control module configured to receive a command message for instructing self-fault diagnosis of the electric vehicle charger from a control system and set a test mode for self-fault diagnosis based on the received command message; and
a self-fault diagnosis module configured to perform a self-fault diagnosis-related test in a plurality of states of the set test mode to confirm a status of the electric vehicle charger, and transmit a report message including information on the confirmed status of the electric vehicle charger to the communication control module.

2. The electric vehicle charger of claim 1, wherein the self-fault diagnosis module includes
a charging terminal installed in the self-fault diagnosis module, a charging plug being mated with the charging terminal;
an emulator configured to test charging and discharging of the electric vehicle;
a voltage and current measurement module configured to measure a voltage and current during a charging test of the electric vehicle; and
a variable load module configured to reflect a change in an electric vehicle charging mode.

3. The electric vehicle charger of claim 2, wherein the charging terminal is the same as that of the electric vehicle with which the charging plug is mated.

4. The electric vehicle charger of claim 2, wherein the variable load module is set to a constant current (CC) mode, a constant power (CP) mode, or a constant voltage (CV) mode.

5. The electric vehicle charger of claim 2, wherein the self-fault diagnosis module and the charging plug are connected by a control pilot (CP) line, a proximity pilot (PP) line, a protective earth (PE) line, an AC line, and a DC line.

6. The electric vehicle charger of claim 5, wherein the plurality of states are an unmated state, a mated state, an initialized state, a cable check state, a precharge state, a charge state, and a power down state.

7. The electric vehicle charger of claim 6, wherein the information on the status of the electric vehicle charger includes information on a normal state or error state of the electric vehicle charger.

8. The electric vehicle charger of claim 7, wherein
the unmated state is a state for setting a test mode for testing of the self-fault diagnosis, and
the setting of the test mode is a setting of at least one of whether or not high level communication is supported, an identification mode, an authentication and approval mode, a charging mode, a maximum current and voltage acceptable for device safety, a charging test time, a charging energy amount, or an available maximum current.

9. The electric vehicle charger of claim 8, wherein the presence or absence of an error in the unmated state is determined by confirming a setting value of the test mode or a voltage of the CP line.

10. The electric vehicle charger of claim 7, wherein
the mated state is a state for confirming a physical connection of the self-fault diagnosis module, and
the presence or absence of an error in the mated state is determined by confirming a voltage of the CP line, a voltage of the PE line, or a voltage of the PP line.

11. The electric vehicle charger of claim 7, wherein
the initialized state is a state for performing a test for low level communication, and
the presence or absence of an error in the initialized state is determined based on whether a signal having a certain ratio of duty cycle is transmitted, a comparison of a DC output voltage with a threshold voltage, and whether a pulse width modulation (PWM) duty cycle matches a maximum allowable current.

12. The electric vehicle charger of claim 7, wherein the presence or absence of an error in the cable check state is determined by confirming a voltage of the CP line and based on a result of an insulation test in DC charging.

13. The electric vehicle charger of claim 7, wherein the presence or absence of an error in the precharge state is determined based on whether a precharge-related response signal is received, and through a comparison of a DC voltage with a voltage requested by the self-fault diagnosis module.

14. The electric vehicle charger of claim 7, wherein the presence or absence of an error in the charge state is determined based on whether a power transfer response signal is transmitted for a certain period of time, whether a charge state response signal is transmitted, or whether AC and DC are transmitted with a predefined amount of power.

15. The electric vehicle charger of claim 7, wherein the presence or absence of an error in the power down state is determined based on whether a power transfer response signal is transmitted for a certain period of time, whether a session stop response signal is transmitted, or confirmation of a voltage of the CP line.

16. The electric vehicle charger of claim 1, wherein the test result is included in a data transfer request message defined in open charge point protocol (OCPP).

17. An electric vehicle charger for remotely performing self-fault diagnosis in an electric vehicle charging system, the electric vehicle charger comprising:
a communication control module configured to communicate with a control system and set a test mode for self-fault diagnosis; and
a self-fault diagnosis module, wherein the self-fault diagnosis module periodically performs a self-fault diagnosis-related test in a plurality of states of the set test mode to confirm a state of the self-fault diagnosis module and report an alive message including information on the confirmed state of the self-fault diagnosis module to the communication control module.

18. The electric vehicle charger of claim 17, wherein in the confirmation of the state of the self-fault diagnosis module, a read and write process from and to a register included in the self-fault diagnosis module is performed, and when the read and write process is normal, the alive message is generated.

19. A method for remotely performing self-fault diagnosis in an electric vehicle charger in an electric vehicle charging system, the method comprising:
receiving a command message for instructing self-fault diagnosis of the electric vehicle charger from a control system;
setting a test mode for self-fault diagnosis based on the received command message;
performing a test according to the set test mode to confirm a status of the electric vehicle charger; and
transmitting a report message including information on the confirmed status of the electric vehicle charger.
